(19) United States
(12) Patent Application Publication
(10) Pub. No.: US 2012/0306492 A1
(43) Pub. Date: Dec. 6, 2012

(54) PENETRATION TUBE ASSEMBLIES FOR REDUCING CRYOSTAT HEAT LOAD

(75) Inventors: Ernst Wolfgang Stautner, Niskayuna, NY (US); Kathleen Melanie Amm, Clifton Park, NY (US); Robbi Lynn McDonald, Toronto (CA); Anthony Mantone, Florence, SC (US); John Scaturro, JR., Florence, SC (US); Longzhi Jiang, Florence, SC (US); Weijun Shen, Florence, SC (US)

(73) Assignee: GENERAL ELECTRIC COMPANY, SCHENECTADY, NY (US)

(21) Appl. No.: 13/118,777

(22) Filed: May 31, 2011

(51) Int. Cl. G01R 33/48; F16L 9/00; F16L 9/18

(52) U.S. Cl. 324/309; 138/111; 138/37; 138/114; 138/177

(57) ABSTRACT

A penetration assembly for a cryostat is presented. The penetration assembly includes an outer wall member having a first end and a second end and configured to alter an effective thermal length of the wall member, wherein a first end of the tube is communicatively coupled to a high temperature region and the second end of the tube is communicatively coupled to a cryogen disposed within a cryogen vessel of the cryostat. In addition, the penetration tube assembly includes a telescoping inner wall member comprising a plurality of tubes nested within one another, and wherein each tube in the plurality of tubes is operatively coupled to at least one other tube in series.

### BACKGROUND

Embodiments of the present disclosure relate to cryostats, and more particularly to a design of penetration tube assemblies for use in cryostats, where the penetration tube assemblies are configured to reduce head loads to the cryostat caused by the penetration tube assemblies.

Known cryostats containing liquid cryogens, for example are used to house superconducting magnets for magnetic resonance imaging (MRI) systems or nuclear magnetic resonance (NMR) imaging systems. Typically, the cryostat includes an inner cryostat vessel and a helium vessel that surrounds a magnetic cartridge, where the magnetic cartridge includes a plurality of superconducting coils. Also, the helium vessel that surrounds the magnetic cartridge is typically filled with liquid helium for cooling the magnet. Additionally, a thermal radiation shield surrounds the helium vessel. Moreover, an outer cryostat vessel, a vacuum vessel surrounds the high temperature thermal radiation shield. In addition, the outer cryostat vessel is generally evacuated.

The cryostat generally also includes at least one penetration through the vessel walls, where the penetration is configured to facilitate various connections to the helium vessel. It may be noted that these penetrations are designed to minimize thermal conduction between the vacuum vessel and the helium vessel, while maintaining the vacuum between the vacuum vessel and the helium vessel. Moreover, it is desirable that the penetrations also compensate for differential thermal expansion and contraction of the vacuum vessel and the helium vessel. In addition, the penetration also provides a flow path for helium gas in case of a magnet quench.

Any penetration potentially increases the heat load to a cryostat from room temperature to cryogenic temperatures. The heat load mechanisms typically include thermal conduction, thermal macro and micro convection, thermal radiation. Additionally, heat load mechanisms also include thermal conduction of material, thermal link to the coldhead, thermal conduction of a helium column, thermal radiation from a side to the top of the cryostat, and thermal contact link to a cryocooler. Unlike cryostat penetrations that are open to atmosphere and are cooled by the escaping helium gas flow, closed or hermetically sealed penetrations on a cryostat are a major source of heat input for a cryostat. Additionally, penetrations are generally equipped with a safety means to ensure the quick and safe release of cryogenic gas in case of a sudden energy dump or quench of the magnet or a vacuum failure or an ice blockage.

Traditionally, early NMR and MRI systems have used boil-off from the helium bath of the cryostat and routed the boil-off gas around or through the penetration for heat exchange. The presence of a heat exchange gas within a penetration can be used for efficient cooling. In particular, if designed properly, the presence of the heat exchange gas substantially minimizes the heat load to the cryogenic system. However, NMR and MRI magnet systems, as well as other cryogenic applications, no longer permit the release of gas to the atmosphere through the penetration due to cost reasons. Additionally, due to considerable increase in the cost of helium, cryogenic systems are completely recondensing the boil-off gas.

Unfortunately, since the cooling of the gas stream is no longer available, penetrations add a considerable part to the overall heat load budget. Furthermore, the parasitic heat load of a penetration can be as high as 20 to 40% of the total heat load to the cryostat. This heat load disadvantageously leads to an inconvenient and expensive premature replacement and refurbishment of the cryocooler. The cryocooler replacement in turn increases the life-cycle cost of the MRI magnet for example.

Additionally, certain other presently available techniques for reducing the cryostat heat load caused by penetration tube assemblies entail cooling of the penetration tube assembly using a heat station linked to a coldhead cooling stage that acts as a heat sink. Unfortunately, use of these techniques reduces the cooling power of the coldhead. Moreover, other techniques address the problem of reducing the cryostat head load caused by the penetration tube assemblies by minimizing the physical dimensions of the penetration tube assemblies. However, minimizing the dimensions of the penetration tube assemblies can adversely affect the cryostat at high quench rates by leading to an increase in the internal pressure that is considerably higher than the design pressure. Moreover, bellows have been traditionally used as the penetration tube, where the convolutions of the bellows provide additional thermal length. However, even with the additional thermal length, the thermal conduction load from the bellows to the helium vessel can be significant.

It may therefore be desirable to develop a robust design of a penetration tube assembly that advantageously reduces the heat load to the cryostat caused by the penetration tube assembly, while enhancing the life span of the cryocooler.

### BRIEF DESCRIPTION

In accordance with aspects of the present technique, a penetration assembly for a cryostat is presented. The penetration assembly includes an outer wall member having a first end and a second end and configured to alter an effective thermal length of the wall member, wherein a first end of the tube is communicatively coupled to a high temperature region and the second end of the tube is communicatively coupled to a cryogen disposed within a cryogen vessel of the cryostat. In addition, the penetration tube assembly includes a telescoping inner wall member comprising a plurality of tubes nested within one another, and wherein each tube in the plurality of tubes is operatively coupled to at least one other tube in series.

In accordance with another aspect of the present technique, a penetration assembly for a cryostat is presented. The penetration assembly includes a corrugated outer wall member having a first end and a second end and configured to alter an effective thermal length of the corrugated outer wall member, wherein a first end of the tube is communicatively coupled to a high temperature region and the second end of the tube is communicatively coupled to a cryogen disposed within a cryogen vessel of the cryostat. Furthermore, the penetration assembly includes an inner wall member having a first end and a second end and disposed adjacent to the corrugated outer wall member.

In accordance with yet another aspect of the present technique, a system for magnetic resonance imaging is presented. The system includes an acquisition subsystem configured to acquire image data representative, wherein the acquisition subsystem includes a superconducting magnet configured to receive the patient therein, a cryostat comprising a cryogen vessel in which the superconducting magnet is contained, wherein the cryostat includes a heat load optimized penetration assembly including an outer wall member having a first end and a second end and configured to alter an effective thermal length of the wall member, wherein a first end of the tube is communicatively coupled to a high temperature region and the second end of the tube is communicatively coupled to a cryogen disposed within a cryogen vessel of the cryostat and an inner wall member disposed adjacent to the outer wall member. Additionally, the system includes a processing subsystem in operative association with the acquisition subsystem and configured to process the acquired image data.

### DRAWINGS

These and other features, aspects, and advantages of the present disclosure will become better understood when the following detailed description is read with reference to the accompanying drawings in which like characters represent like parts throughout the drawings, wherein:

FIG. 1 is a partial cross-sectional view of a cryostat structure;

FIG. 2 is a schematic illustration of a part of an axial cross-sectional view of one embodiment of a wall member of a penetration tube assembly for use in the cryostat of FIG. 1, in accordance with aspects of the present technique; and

FIG. 3 is a schematic illustration of a part of an axial cross-sectional view of another embodiment of a wall member of a penetration tube assembly for use in the cryostat of FIG. 1, in accordance with aspects of the present technique.

### DETAILED DESCRIPTION

As will be described in detail hereinafter, various embodiments of a penetration tube assembly for use in a cryostat and configured to enhance an effective thermal length of the penetration tube assembly are presented. Particularly, the various embodiments of the penetration tube assemblies reduce the heat load to the cryostat caused by the penetration tube assemblies by enhancing the effective thermal length of the penetration tube assembly. By employing the penetration assemblies described hereinafter, cryostat heat loads caused by penetrations may be dramatically reduced.

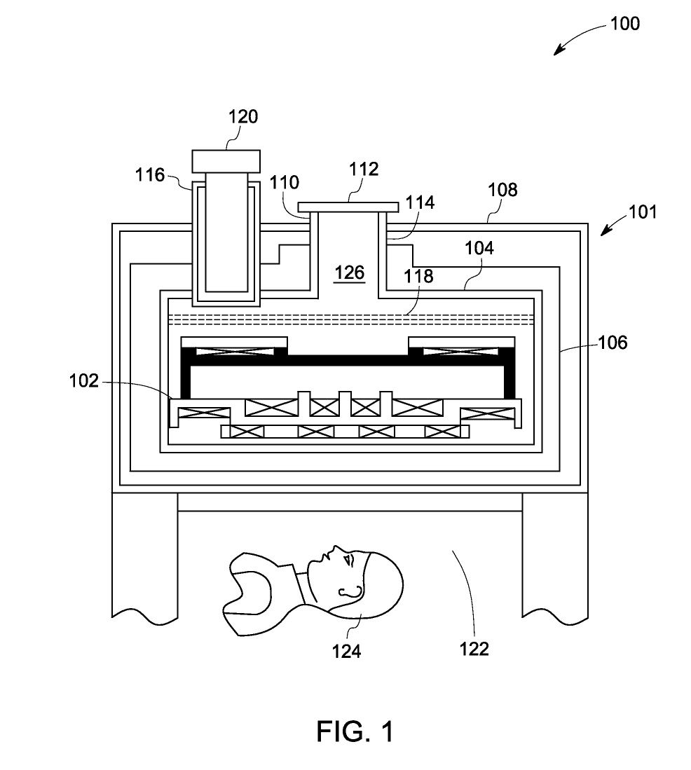

Referring to FIG. 1, a schematic diagram 100 of a sectional view of a magnetic resonance imaging (MRI) system that includes a cryostat 101 is depicted. The cryostat 101 includes a superconducting magnet 102. Moreover, the cryostat 101 includes a toroidal cryogen vessel 104, which surrounds the magnet cartridge 102 and is filled with a cryogen 118 for cooling the magnets. The cryogen vessel 104 may also be referred to as an inner wall of the cryostat 101. The cryostat 101 also includes a toroidal thermal radiation shield 106, which surrounds the cryogen vessel 104. In addition, the cryostat 101 includes a toroidal vacuum vessel or outer vacuum chamber (OVC) 108, which surrounds the thermal radiation shield 106 and is typically evacuated. The OVC may also be referred to as an outer wall of the cryostat 101. Furthermore, the cryostat 101 includes a penetration tube assembly 110, which penetrates the cryogen vessel 104 and outer vacuum chamber 108 and the thermal radiation shield 106, thereby providing access for the electrical leads. In the embodiment depicted in FIG. 1, the penetration tube assembly 110 is a closed penetration assembly having a cover plate 112, in certain embodiments. Also, reference numeral 126 is generally representative of an opening in the penetration tube assembly 110.

Also, reference numeral 114 is generally representative of a wall member of the penetration tube assembly 110. It may be noted that a first end of the wall member 114 may be operationally coupled to the OVC 108, while a second end of the wall member 114 may be operationally coupled to the cryogen vessel 104. Accordingly, the first end of the wall member 114 may be at a first temperature of about 300 degrees Kelvin (K), while the second end of the wall member 114 may be at a temperature of about 4 degrees K.

Moreover, the cryogen 118 in the cryogen vessel 104 may include helium, in certain embodiments. However, in certain other embodiments, the cryogen 118 may include liquid hydrogen, liquid neon, liquid nitrogen, or combinations thereof. It may be noted that in the present application, the various embodiments are described with reference to helium as the cryogen 118. Accordingly, the terms cryogen vessel and helium vessel may be used interchangeably.

Also, as depicted in FIG. 1, the MRI system 100 includes a sleeve 116. In certain embodiments, a cryocooler 120 may be disposed in the sleeve 116. The cryocooler 120 is employed to cool the cryogen 118 in the cryogen vessel 104. Furthermore, reference numeral 122 is generally representative of a patient bore. A patient 124 is typically positioned within the patient bore 124 during a scanning procedure.

As previously noted, any penetration potentially leads to an increase in the heat load to a cryostat from room temperatures to cryogenic temperatures. In accordance with aspects of the present technique, various embodiments of penetration tube assemblies for use in a cryostat, such as the cryostat 101 of FIG. 1, and configured to reduce the heat load to the cryostat 101 are presented. Particularly, the penetration tube assemblies presented hereinafter are configured to reduce the heat load to the cryostat by enhancing the effective thermal length of the penetration tube assemblies.

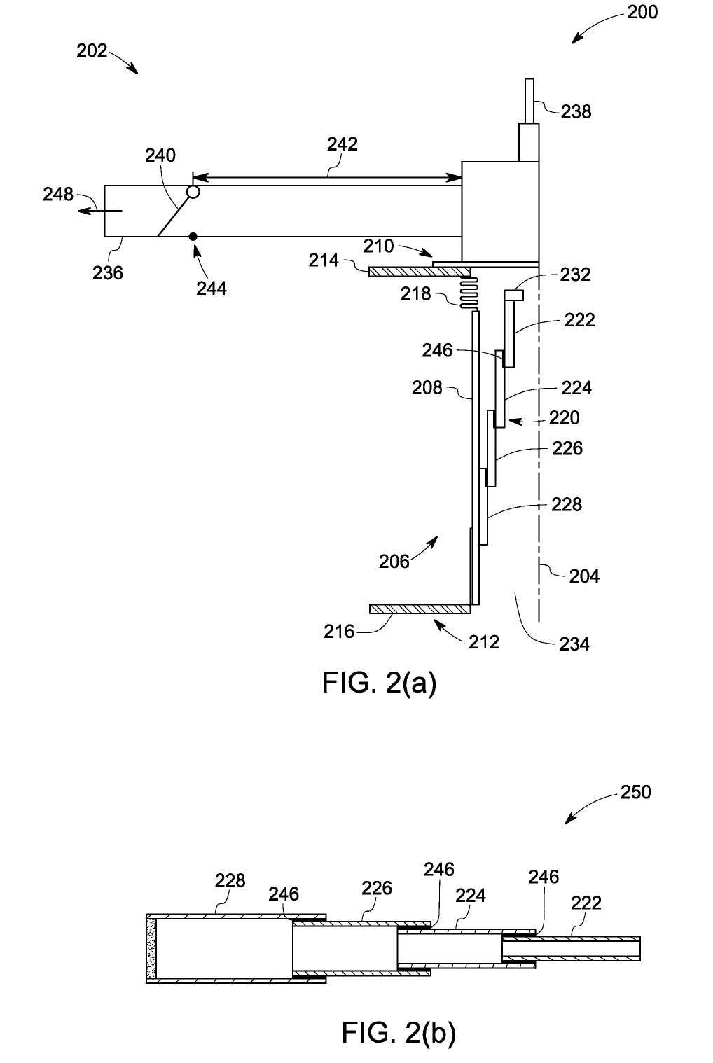

Illustrated in FIG. 2 is one embodiment of an exemplary penetration tube assembly 200 for use in a cryostat, such as the cryostat 101 of FIG. 1. In particular, FIG. 2(a) is a schematic illustration of a part of an axial cross-sectional view 202 of one embodiment of a wall member 206 of a penetration tube assembly for use in the cryostat 101. More specifically, FIG. 2 illustrates a part of the penetration tube assembly disposed on one side of the axis of symmetry 204 of the penetration tube assembly 200. In accordance with aspects of the present technique, the exemplary penetration tube assembly 200 includes a wall member 206 that is configured to enhance an effective thermal length of the wall member 206, thereby aiding in reducing the heat load to the cryostat 101 caused by the penetration tube assembly. The term effective thermal length is generally used to refer to a length of a thermal conduction path of the wall member 206. In one embodiment, the penetration tube assembly 200 may be configured to enhance the effective length of the thermal conduction path in a range from about 50 mm to about 300 mm.

According to aspects of the present technique, the wall member 206 of the penetration tube assembly 200 is configured to alter and more particularly enhance the effective thermal length of the penetration tube assembly 200. It may be noted that the terms effective thermal length and thermal conduction path length are used interchangeably. To that end, in the exemplary embodiment of FIG. 2, the wall member 206 includes an outer wall member 208 and an inner wall member 220.

The outer wall member 208 includes a thin-walled tube. Furthermore, in certain embodiments, the outer wall member 208 is a thin-walled stainless steel tube. By way of example, in one embodiment, the penetration tube assembly may include a cylindrical tube having a thin-walled circular cross-section.

In the embodiment depicted in FIG. 2, the outer wall member 208 has a first end 210 and a second end 212. In a presently contemplated configuration of FIG. 2, the first end 210 of the outer wall member 208 may be coupled to a corrugated tube member 218. The corrugated tube member 218 is in turn coupled to the OVC 108 (see FIG. 1) of the cryostat 101 via a first flange 214. In certain embodiments, the first flange 214 may be formed using stainless steel or aluminum.

Furthermore, the second end 212 of the outer wall member 208 may be coupled to the cryogen vessel 104 (see FIG. 1) of the cryostat 101. In one embodiment, the second end 212 of the outer wall member 208 may be coupled to the cryogen vessel 104 using a second flange 216. In one embodiment, the second flange 212 may include a stainless steel flange. However, copper and/or aluminum may be used to form the second flange 216.

As previously noted, the first end 210 of the outer wall member 208 is coupled to the OVC 108 via the corrugated tube member 218 and the first flange 214. Accordingly, the first end 210 of the outer wall member 208 is communicatively coupled to a high temperature region. Similarly, as the second end 212 of the outer wall member 208 is communicatively coupled to a cryogen 118 (see FIG. 1) disposed within the cryogen vessel 104 of the cryostat 101, the second end 212 of the outer wall member 208 is communicatively coupled to a low temperature region. Also, the high temperature region may have a temperature in a range from about 250 degrees Kelvin (K) to about 300 degrees K. Accordingly, the first end 210 of the outer wall member 208 that is communicatively coupled to the high temperature region may be at a temperature in a range from about 250 degrees K to about 300 degrees K.

It may be noted that the cryogen may include liquid helium, liquid hydrogen, liquid neon, liquid nitrogen, or combinations thereof. Also, as the second end 212 of the outer wall member 208 is in operative association with the cryogen 118 disposed within the cryogen vessel 104 of the cryostat 101, the second end 212 of the outer wall member 208 may be coupled to a low temperature region. The low temperature region may be at a temperature in a range from about 4 degrees K to about 80 degrees K based on the cryogen in use, in certain applications. By way of example, if the cryogen is liquid hydrogen, then the lower temperature region may be at a temperature of about 20 degrees K. Also, if the cryogen is liquid neon, then the lower temperature region may be at a temperature of about 27 degrees K. In addition, for other cryogens, the lower temperature region may be at a temperature in a range from about 4 degrees K to about 80 degrees K.

As will be appreciated, in the case that helium is used as the cryogen 118 (see FIG. 1) there exists a temperature gradient from about 300 degrees K to about 4 degrees K across the length of the penetration tube assembly during normal operation of the cryostat. However, during a quench, this temperature gradient fades and consequently there is a substantially uniform temperature over the whole length of the penetration tube assembly, thereby reducing the temperature of the penetration tube assembly to a range from about 5 degrees K to about 15 degrees K. This lack of a temperature gradient disadvantageously increases the stress and strain in the penetration tube assembly and may result in the shrinkage of the thin-walled tube of the outer wall member 208 during a quench of the magnet. In the embodiment of FIG. 2, the corrugated tube member 218 is configured to aid in enhancing the effective thermal length of the outer wall member 208. Particularly, the corrugated tube member 218 is employed to compensate for the shrinkage of the thin-walled tube 208 during the quench. More specifically, the corrugated tube member 218 expands during the quench, thereby compensating for the shrinkage of the thin-walled tube 208 during the quench and substantially minimizing axial stress concentrations within the penetration tube assembly.

In accordance with exemplary aspects of the present technique, the wall member 206 includes a telescoping inner wall member 220. The telescoping inner wall member 220 is configured to enhance the pressure bearing capability of the wall member 206, especially during a quench. In particular, the telescoping inner wall member 220 includes a plurality of tubes nested within one another. Specifically, in one embodiment, the telescoping inner wall member 220 includes a plurality of concentric tubes of varying diameters nested within one another. In the example depicted in FIG. 2, the telescoping inner wall member 220 includes a first tube 222, a second tube 224, and a third tube 226, and a fourth tube 228 that are concentrically nested within one another. Particularly, each tube is operatively coupled to at least one other tube in series. By way of example, a second end of the first tube 222 is operatively coupled to a first end of the second tube 224, while a second end of the second tube 224 is operatively coupled to a first end of the third tube 226. In a similar fashion, a second end of the third tube 226 is operatively coupled to a first end of the fourth tube 228. Moreover, a second end of the fourth tube 228 is coupled to the second end 212 of the outer wall member 208. This coupling of the tubes 222, 224, 226, 228 forms a serial connection. Accordingly, the tubes 222, 224, 226, 228 are nested into one another in series instead of one long tube. Also, in one embodiment, the tubes 220, 224, 226, 228 may include stainless steel tubes of varying diameters. However, other materials, such as, but not limited to, alloys of Titanium, Inconel, non-metallic epoxies and carbon fiber reinforced tubes, may be used to form the tubes 222, 224, 226, 228. Although the configuration of FIG. 2 depicts the telescoping inner wall member 220 as including four concentric tubes 222, 224, 226, 228 nested within one another, use of other number of concentric tubes is also envisaged.

In one embodiment, coupling elements or stoppers 246 may be employed to aid in coupling each tube to at least one other tube in the plurality of concentric tubes of the telescoping inner wall member 220. Furthermore, in accordance with aspects of the present techniques, the telescoping inner wall member 220 is generally positioned in a collapsed configuration (see FIG. 2(c)). However, during a quench of the magnet, the telescoping inner wall member 220 is transitioned from the collapsed configuration of FIG. 2(c) to an expanded configuration (see FIG. 2(a) and FIG. 2(b)). To that end, the stoppers 246 are positioned near a first end of the tubes 224, 226 and 228, for example. During a quench, while the telescoping inner wall member 220 transitions from the collapsed configuration to the expanded configuration, an inner tube slides up until that tube encounters a stopper 246 corresponding to a neighboring concentric tube. By way of example, the third tube 226 slides up until the third tube 226 encounters the stopper 246 corresponding to the fourth tube 228. In certain other embodiments, an annular rim (not shown in FIG. 2) on each of the tubes may be used to aid in coupling the tubes to one another. Alternatively, vertical slots (not shown in FIG. 2) on the tubes may be provided. In addition, mating protrusions (not shown in FIG. 2) may be provided on the sliding concentric tubes to aid in coupling the tubes.

Additionally, a venting element 232 is coupled to a first end of an innermost tube in the plurality of tubes. By way of example, the venting element 232 may be coupled to the first end of the first tube 222. In certain embodiments, the venting element 232 may include a burst disk. Alternatively, a valve may be coupled to the first end of the first tube 222. It may be noted that in certain embodiments, the burst disk may be a replaceable burst disk, while the valve may be a quench valve.

Furthermore, it may be noted that the use of the burst disk 232 aids in hermetically closing the cryogen vessel 104. The complete closure of the cryogen vessel 104 by using the burst disk 232 or a valve as opposed to leaving an opening free allows evacuation of a space above the cryogen vessel 104, thereby eliminating the helium gas column. Specifically, the use of the burst disk 232 aids in the reduction of heat load caused by the penetration tube assembly to the cryostat 101. By way of example, based on the design of the penetration tube assembly, a reduction in the total thermal cryogenic budget in a range from about 50 mW to 150 mW can be achieved.

With continuing reference to FIG. 2, the penetration tube assembly 200 may be operationally coupled to a vent line 236. In one embodiment, the vent line 236 may be operationally coupled to the first end 210 of the outer wall member 208. The vent line 236 aids in channelizing the cryogen flow during a quench of the magnet. Furthermore, the vent line 236 is generally filled with a cryogen such as helium gas. Filling the vent line 236 with helium gas aids in ensuring that the penetration tube assembly is not exposed to ambient air. Additionally, the vent line 236 includes a flap valve 240. Further, the flap valve 240 is configured to protect the vent line 236 from the ingress of air. Also, an O-ring seal 244 may be employed to aid in the opening and closing of the flap valve 240. The O-ring sealed spring-actuated flap valve 240 is typically in a closed position as shown in FIG. 2 and is opened only during a quench. It may be noted that the flap valve 240 is opened typically during a quench in a gas flow direction 248.

Moreover, in one embodiment, the vent line 236 includes a vent line port 238. The vent line port 238 aids in evacuating the vent line 236. Particularly, when vacuum is pulled on the vent line port 238, the flap valve 240 moves in the direction that is opposite to the gas flow direction 248. Consequently, the penetration tube assembly and the vent line 236 are evacuated. Particularly, the penetration tube assembly and a portion 242 of the vent line 236 up to a position of the flap valve 240 may be evacuated. The vent line port 238 may be used to evacuate the portion 242 of the vent line 236, which in turn forces the flap valve 242 to the closed position.

Implementing the penetration tube assembly along with the vent line 236 as depicted in FIG. 2 and the use of the burst disk 232 that hermetically closes the cryogen vessel 104 allows evacuation of the penetration tube assembly, thereby resulting in reduction of the heat load to the cryostat 101 by eliminating the helium gas column.

Moreover, in the case where no burst disk is coupled to the inner wall member 220, the relatively small diameter of the inner wall member 220 is left open, thereby resulting in the formation of a helium gas column. In this situation, the flap valve 240 in the vent line 236 protects the vent line 236 and/or the penetration tube assembly from ingress of air. However, the embodiment of the penetration tube assembly that does not include a burst disk coupled to the inner wall member results in a higher heat load to the cryostat since the helium gas column conducts heat from about 300 degrees K to about 4 degrees K.

It may also be noted that an outermost tube of the telescoping inner wall member 220, such as the fourth tube 228, may be coupled to the outer wall member 208. In one embodiment, the fourth tube 228 may be coupled to the second end 212 of the outer wall member 208.

Turning now to FIG. 2(b), a schematic illustration of a part of an axial cross-sectional view 250 of the telescoping inner wall member 220 of FIG. 2(a) in an expanded configuration is depicted. Particularly, FIG. 2(b) depicts the expanded configuration of the telescoping inner wall member 220 during a quench of the magnet.

Referring now to FIG. 2(c), a top view 252 of the telescoping inner wall member 220 of FIG. 2(a) in a collapsed configuration is depicted. In normal operation, the telescoping inner wall member 220 is in a collapsed configuration, as depicted in FIG. 2(c). However, during a quench, pressure in the cryogen vessel 104 increases. Consequent to the increase in pressure in the cryogen vessel 104, the telescoping inner wall member 220 is transitioned from the collapsed configuration of FIG. 2(c) to the expanded configuration of FIG. 2(a) and FIG. 2(b) during a quench. Specifically, the telescoping tubes 222, 224, 226, 228 expand as depicted in FIG. 2(a) and allow the cryogen, such as helium, to escape and vent through the vent line 236 that is coupled to the penetration tube assembly. By way of example, the cryogen 118 escapes and vents from the cryogen vessel 104 through an opening 234 in the penetration tube assembly to the vent line 236.

With continuing reference to FIG. 2, in accordance with exemplary aspects of the present technique, the serial connection of the plurality of tubes 222, 224, 226, 228 enhances the pressure bearing capability of the wall member 206 and more particularly the pressure bearing capability of the inner wall member 220 during a quench. In particular, the serial coupling of the tubes 222, 224, 226, 228 permits the inner wall member 220 to be transitioned from the collapsed configuration of FIG. 2(c) to the expanded configuration of FIG. 2(a) and FIG. 2(b). After the quench, once the pressure drops, the tubes 220, 224, 226, 228 automatically collapse and return the inner wall member 220 to the collapsed configuration.

As described hereinabove, the telescoping inner wall member 220 includes a plurality of concentric tubes. It may be noted that use of collapsible steel and/or plastic cups, collapsible telescopes, collapsible antennae, or combinations thereof as the inner wall member 220 is also envisaged.

Implementing the penetration assembly as described with reference to FIG. 2 provides an effective thermal conduction path of enhanced length, especially during a quench, thereby reducing the heat load to the cryostat caused by the penetration tube assembly. Specifically, the telescoping inner wall member 220 of the penetration tube assembly 200 as depicted in FIG. 2 enhances the effective thermal length of the penetration tube assembly 200 by transitioning from the collapsed configuration of FIG. 2(c) to the expanded configuration of FIGS. 2(a) and 2(b) during a quench. This increase in the effective thermal length of the wall member 206 of the penetration tube assembly 200 in turn results in an increase in the opening surface area of the penetration tube assembly 200. Consequently, there is an increase in the available cross-sectional area of the penetration tube assembly 200 during the quench of the magnet without additional heat load penalty. This increase in the available cross-sectional area of the penetration tube assembly 200 in turn facilitates enhanced dissipation of heat, thereby reducing the head load to the cryostat caused by the penetration tube assembly.

Additionally, implementing the penetration assembly as described with reference to FIG. 2 allows use of a thin-walled tube for the inner wall member 220. Also, the inner wall member 220 is reinforced only during a quench. In addition, the inner wall member 220 partially closes the opening 234 in the penetration tube assembly after a quench.

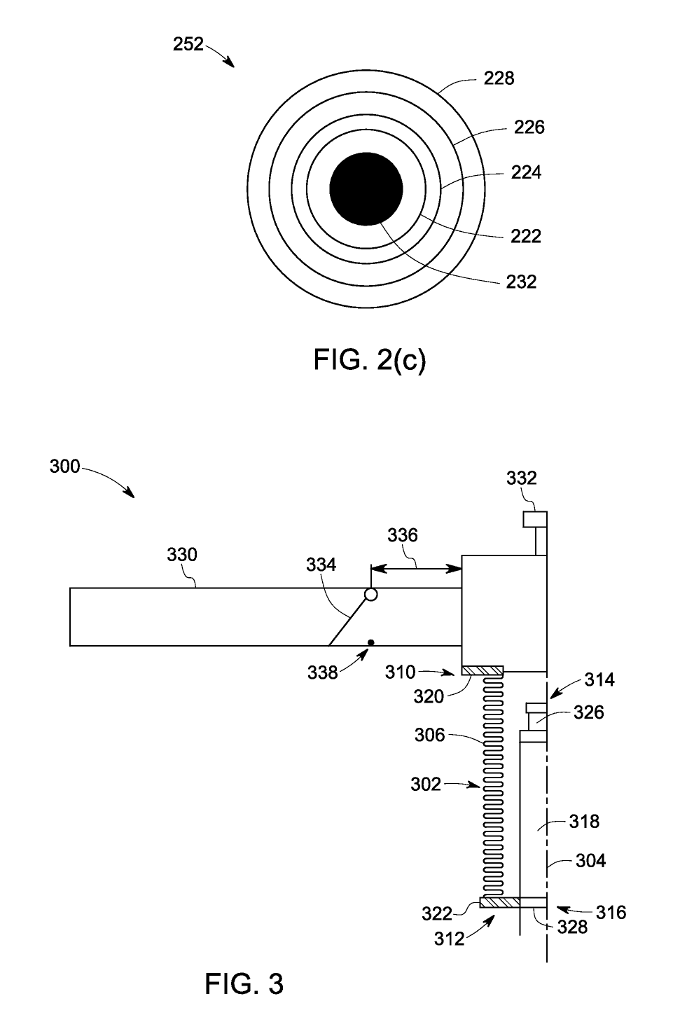

Referring now to FIG. 3, another embodiment 300 of an exemplary wall member 302 of a penetration tube assembly configured for use in a cryostat, such as the cryostat 101 of FIG. 1, is depicted. Particularly, FIG. 3 is a schematic illustration of a part of an axial cross-sectional view of another embodiment of a wall member 302 of a penetration tube assembly for use in the cryostat. Also, reference numeral 304 is generally representative of the axis of symmetry of the penetration tube.

In accordance with exemplary aspects of the present technique, the wall member 302 has an outer wall member 306 and an inner wall member 318. The outer wall member 306 has a first end 310 and a second end 312. In a similar fashion, the inner wall member 318 has a corresponding first end 314 and second end 316. The outer wall member 306 includes a thin-walled corrugated tube. The corrugated tube may be formed from stainless steel, in certain embodiments. In certain other embodiments, the corrugated tube may also be formed and/or reinforced using glass fiber reinforced plastic (GRP). Moreover, the first end 310 of the outer wall member 306 is coupled to the OVC 108 (see FIG. 1) via a first flange 320, while the second end 312 of the outer wall member 306 is coupled to cryogen vessel 104 (see FIG. 1) via a second flange 322. It may be noted that the first and second flanges 320, 322 may be stainless steel flanges. Alternatively, the first and second flanges 320, 322 may be formed using copper and/or aluminum.

Additionally, the inner wall member 318 is a thin-walled tube fitted with a venting element 326. In one embodiment, the venting element 326 may include a burst disk. Alternatively, a valve may be employed instead of the burst disk 326. In particular, the burst disk 326 is coupled to the first end 314 of the inner wall member 318. Also, the thin-walled inner wall member 318 may have a relatively small diameter. By way of example, in certain embodiments, the thin-walled inner wall member 318 may have a diameter in a range from about 50 mm to about 100 mm. It may further be noted that the diameter of the thin-walled inner wall member 318 is selected based on a cryogen inventory volume and/or magnet quench energy. The inner wall member 318 may be formed using stainless steel, in one embodiment. In certain other embodiments, the inner wall member 308 may be reinforced using GRP or carbon fiber composite (CFC).

Furthermore, in certain embodiments, the inner wall member 318 may be coupled to the cryogen vessel 104 of the cryostat 101. Additionally, the inner wall member 318 is also coupled to a vent line 330 that can be evacuated. In one embodiment, the inner wall member 318 may be coupled to a bottom plate of the penetration assembly. Hence, the “fixed” inner wall member 318 is maintained at a desired height to allow quick and convenient burst disk replacement after a quench. Moreover, the length of the inner wall member 318 is chosen such that the chosen length of the inner wall member 318 allows the burst disk 326 to be maintained at room temperature. Also, the second end 316 of the inner wall member 318 includes a smooth, rounded entry 328 that aids in providing a lower entrance pressure drop during a quench.

As will be appreciated, there exists a temperature gradient from about 300 degrees K to about 4 degrees K across the length of the penetration tube assembly during normal operation of the cryostat. However, during a quench, this temperature gradient fades and consequently there is a substantially uniform temperature over the whole length of the penetration tube assembly, thereby reducing the temperature of the penetration tube assembly to a range from about 5 degrees K to about 15 degrees K. This lack of a temperature gradient disadvantageously increases the stress and strain in the penetration tube assembly and may result in the shrinking of the outer wall member 306 during a quench of the magnet. In the embodiment of FIG. 3, the corrugated outer wall member 306 is configured to aid in enhancing the effective thermal length of the wall member 302. Particularly, the corrugated tube member 306 expands during the quench and substantially minimizing axial stress concentrations within the tube.

During a quench, the pressure in the cryogen vessel 104 increases. The cryogen 118 (see FIG. 1) enters the inner wall member 318 through the rounded entry 328. As the pressure in the cryogen vessel 104 increases, the burst disk 326 opens and allows the cryogen to escape, thereby alleviating the pressure buildup in the cryogen vessel.

As previously noted with reference to FIG. 2, the use of the burst disk 326 aids in hermetically closing the cryogen vessel 104. The complete closure of the cryogen vessel 104 by using the burst disk 326 or a valve as opposed to leaving an opening free allows evacuation of a space above the cryogen vessel 104, thereby eliminating the helium gas column. Specifically, the use of the burst disk 326 aids in the reduction of heat load caused by the penetration tube assembly to the cryostat 101. By way of example, based on the design of the penetration tube assembly, a reduction in the total thermal cryogenic budget in a range from about 50 mW to 150 mW can be achieved.

With continuing reference to FIG. 3, the penetration tube assembly 300 may be operationally coupled to a vent line 330. In one embodiment, the vent line 330 may be operationally coupled to the first end 310 of the outer wall member 306. The vent line 330 aids in channelizing the cryogen flow during a quench of the magnet. Moreover, in one embodiment, the vent line 330 includes a vent line port 332. The vent line port 332 aids in evacuating the vent line 330. Additionally, the vent line 330 includes an O-ring sealed spring-actuated flap valve 334. Further, the flap valve 334 is configured to protect the vent line 330 from the ingress of air. The flap valve 334 is typically in a closed position as shown in FIG. 3. It may be noted that the flap valve 334 is opened typically during a quench. Reference numeral 338 is generally representative of an O-ring seal.

Also, the vent line 330 is generally filled with a cryogen such as helium gas. Filling the vent line 330 with helium gas aids in ensuring that the penetration tube assembly is not exposed to ambient air. Also, the flap valve 334 is typically in a closed position and is opened only during a quench.

However, in certain embodiments, the penetration tube assembly and the vent line 330 may be evacuated. Particularly, the penetration tube assembly and a portion 336 of the vent line 330 up to a position of the flap valve 334 may be evacuated. The vent line port 332 may be used to evacuate the portion 336 of the vent line 330, which in turn forces the flap valve 336 to the closed position.

Implementing the penetration tube assembly along with the vent line 330 as depicted in FIG. 3 and the use of the burst disk 326 that hermetically closes the cryogen vessel 104 allows evacuation of the penetration tube assembly, thereby resulting in reduction of the heat load to the cryostat 101 by eliminating the helium gas column.

Moreover, in the case where no burst disk is coupled to the inner wall member 318, the relatively small diameter of the inner wall member 318 is left open, thereby resulting in the formation of a helium gas column. In this situation, the flap valve 334 in the vent line 330 protects the vent line 330 and/or the penetration tube assembly from ingress of air. However, the embodiment of the penetration tube assembly that does not include a burst disk coupled to the inner wall member results in a higher heat load to the cryostat since the helium gas column conducts heat from about 300 degrees K to about 4 degrees K.

Implementing the penetration assembly as described with reference to FIG. 3 provides an effective thermal conduction path of enhanced length. Specifically, the corrugated outer wall member 306 of the penetration tube assembly 300 as depicted in FIG. 3 enhances the effective thermal length of the penetration tube assembly 300. This increase in the effective thermal length of the outer wall member 306 of the penetration tube assembly 300 in turn results in an increase in the opening surface area of the penetration tube assembly 300. Consequently, there is an increase in the available cross-sectional area of the penetration tube assembly 300 during the quench of the magnet without additional heat load penalty.

Also, the embodiment of FIG. 3 allows a substantial reduction in the transmission of vibrations from the OVC 108 to the inner cryogen vessel 104. In particular, the embodiment of FIG. 3 allows relatively free movement of the wall member 302 of the penetration tube assembly, thereby reducing transmission of vibrations from the OVC 108 to the cryogen vessel 104 during transport and during a stationary positioning of the cryostat 101. Additionally, the space between the corrugations in the corrugated outer wall member 306 may be evacuated. Accordingly, conduction due to the use of cryogen gas columns of relatively bigger diameter may be circumvented, as previously noted.

In addition, the relatively long length of the corrugated outer wall member 306 substantially minimizes thermal conduction. Also, use of the inner wall member 318 with the burst disk 326 enhances the pressure bearing capability of the penetration tube assembly. Moreover, the penetration assembly is accessible from the top, thereby allowing easy replacement of the burst disk 326.

The various embodiments of the exemplary wall members of the penetration tube assembly configured for use in a cryostat described hereinabove dramatically reduce the heat load to the cryostat caused by the penetration tube assembly by enhancing the effective thermal length of the wall member of the penetration tube assembly. The lower thermal burden on the cryostat advantageously results in increasing the ride-through time, extending coldhead service time, and cost saving. By way of example, the simplified design of the penetration tube assemblies reduces the cost of the overall system. Additionally, use of the exemplary penetration tube assemblies circumvents the need for a thermal link to the coldhead, in certain instances. Furthermore, as previously noted, the penetration accounts for at least 30 to 40% of the heat load of a system. The low heat load to the cryostat resulting from the use of the exemplary penetration tube assemblies described hereinabove potentially aids in reducing the total helium inventory required in a cryostat. The various embodiments of the penetration tube assemblies described hereinabove therefore present a heat load optimized penetration, which is a key factor for successful cryostat design.

While only certain features of the disclosure have been illustrated and described herein, many modifications and changes will occur to those skilled in the art. It is, therefore, to be understood that the appended claims are intended to cover all such modifications and changes as fall within the true spirit of the disclosure.

1. A penetration assembly for a cryostat, the penetration assembly comprising:
an outer wall member having a first end and a second end and configured to alter an effective thermal length of the wall member, wherein a first end of the tube is communicatively coupled to a high temperature region and the second end of the tube is communicatively coupled to a cryogen disposed within a cryogen vessel of the cryostat; and
a telescoping inner wall member comprising a plurality of tubes nested within one another, and wherein each tube in the plurality of tubes is operatively coupled to at least one other tube in series.

2. The penetration assembly of claim 1, wherein the high temperature region has a temperature in a range from about 250 degrees K to about 300 degrees K.

3. The penetration assembly of claim 1, wherein the cryogen comprises liquid helium, liquid hydrogen, liquid neon, liquid nitrogen, or combinations thereof.

4. The penetration assembly of claim 1, further comprising a venting element operatively coupled to a first end of an innermost tube in the plurality of concentric tubes.

5. The penetration assembly of claim 4, wherein the venting element comprises a burst disk, a burst valve or a combination thereof.

6. The penetration assembly of claim 1, wherein the plurality of tubes in the telescoping inner wall member comprises a plurality of concentric tubes nested within one another.

7. The penetration assembly of claim 6, wherein the plurality of tubes in the telescoping inner wall member comprises stainless steel tubes, TiAl₆V₄ tubes, aluminum tubes, or combinations thereof.

8. The penetration assembly of claim 1, wherein the outer wall member further comprises a corrugated section operatively coupled to the first end, the second end, or both the first end and the second end of the outer wall member.

9. The penetration assembly of claim 8, wherein the corrugated section is configured to alter the effective thermal length of the wall member in a range from about 50 mm to about 300 mm.

10. The penetration assembly of claim 1, wherein the telescoping inner wall member is configured to be in a collapsed configuration.

11. The penetration assembly of claim 10, wherein the telescoping inner wall member is configured to transition from the collapsed configuration to an expanded configuration during a quench.

12. The penetration assembly of claim 11, wherein the telescoping inner wall member is configured to returned to the collapsed configuration after the quench.

13. The penetration assembly of claim 1, further comprising a vent line operationally coupled to the outer wall member and configured to aid in channelizing cryogen flow during a quench of the magnet.

14. The penetration assembly of claim 13, wherein the vent line comprises:
a vent line port configured to aid in evacuating the vent line; and
a flap valve configured to prevent ingress of air into the vent line.

15. A penetration assembly for a cryostat, the penetration assembly comprising:
a corrugated outer wall member having a first end and a second end and configured to alter an effective thermal length of the corrugated outer wall member, wherein a first end of the tube is communicatively coupled to a high temperature region and the second end of the tube is communicatively coupled to a cryogen disposed within a cryogen vessel of the cryostat; and
an inner wall member having a first end and a second end and disposed adjacent to the corrugated outer wall member.

16. The penetration assembly of claim 15, further comprising a venting element operatively coupled to the first end of inner wall member.

17. The penetration assembly of claim 15, wherein the corrugated outer wall member is configured to alter the effective thermal length of the outer wall member in a range from about 50 mm to about 300 mm.

18. The penetration assembly of claim 15, wherein the inner wall member comprises a thin-walled tube reinforced with glass reinforced plastic.

19. The penetration assembly of claim 15, wherein the second end of the inner wall member is coupled to a bottom plate of the penetration tube assembly.

20. The penetration assembly of claim 15, wherein a region between the inner wall member and the corrugated outer wall member comprises an evacuated region.

21. The penetration assembly of claim 15, further comprising a vent line operationally coupled to the outer wall member and configured to aid in channelizing cryogen flow during a quench of the magnet.

22. The penetration assembly of claim 21, wherein the vent line comprises:
a vent line port configured to aid in evacuating the vent line; and
a flap valve configured to prevent ingress of air into the vent line.

23. A system for magnetic resonance imaging, comprising:
an acquisition subsystem configured to acquire image data representative, wherein the acquisition subsystem comprises:
a superconducting magnet configured to receive the patient therein;
a cryostat comprising a cryogen vessel in which the superconducting magnet is contained, wherein the cryostat comprises a heat load optimized penetration assembly comprising:
an outer wall member having a first end and a second end and configured to alter an effective thermal length of the wall member, wherein a first end of the tube is communicatively coupled to a high temperature region and the second end of the tube is communicatively coupled to a cryogen disposed within a cryogen vessel of the cryostat;
an inner wall member disposed adjacent to the outer wall member; and
a processing subsystem in operative association with the acquisition subsystem and configured to process the acquired image data.
